(19) United States
(12) Patent Application Publication
(10) Pub. No.: US 2025/0125181 A1
(43) Pub. Date: Apr. 17, 2025

(54) LOW TEMPERATURE ELECTROSTATIC CHUCK

(71) Applicant: Applied Materials, Inc., Santa Clara, CA (US)

(72) Inventors: Vijay D. Parkhe, San Jose, CA (US); Onkara Swamy Kora Siddaramaiah, Fremont, CA (US); David Benjaminson, Campbell, CA (US); Ryan Pakulski, Brentwood, CA (US); Anh N. Nguyen, Milpitas, CA (US); Son T. Nguyen, San Jose, CA (US); Prashanth Rao, Karnataka State (IN)

(73) Assignee: Applied Materials, Inc., Santa Clara, CA (US)

(21) Appl. No.: 18/486,072

(22) Filed: Oct. 12, 2023

(51) Int. Cl. H01L 21/683; H01L 21/67

(52) U.S. Cl. CPC H01L 21/6833; H01L 21/67069; H01L 21/67248

(57) ABSTRACT

Exemplary semiconductor processing chambers may include a chamber body. The chambers may include a showerhead positioned atop the body. The chambers may include an electrostatic chuck assembly disposed within the body. The assembly may include a puck that may include a first plate including an electrically insulating material and that defines a substrate support surface. The puck may include a multi-zone heating assembly thermally coupled with the first plate. The puck may include bipolar electrodes. The puck may include a second plate that defines cooling channels. The assembly may include an insulator beneath the second plate. The assembly may include a base plate beneath the insulator. The assembly may include a shaft that may include a heater rod coupled with the heating assembly. The shaft may include a cooling fluid lumen fluidly coupled with the cooling channels. The shaft may include a power rod electrically coupled with a bipolar electrode.

### TECHNICAL FIELD

The present technology relates to semiconductor processes and equipment. More specifically, the present technology relates to chamber components used in etching and/or other processing operations.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Thus, there is a need for improved systems and methods that can be used to produce high quality devices and structures. These and other needs are addressed by the present technology.

### SUMMARY

Exemplary semiconductor processing chambers may include a chamber body. The chambers may include a showerhead positioned atop the chamber body. The chambers may include an electrostatic chuck assembly disposed within an interior of the chamber body. The electrostatic chuck assembly may include a puck. The puck may include a first plate including an electrically insulating material. The first plate may define a substrate support surface. The puck may include a multi-zone heating assembly that is thermally coupled with the first plate. The puck may include a plurality of bipolar electrodes embedded within the electrically insulating material. The puck may include a second plate that defines one or more cooling channels for a heat exchange fluid. The assembly may include at least one thermal insulator disposed beneath the second plate. The assembly may include a facility plate disposed beneath the at least one thermal insulator. The assembly may include a base plate disposed beneath the facility plate. The assembly may include a shaft. The shaft may include at least one heater rod that is coupled with the multi-zone heating assembly. The shaft may include at least one cooling fluid lumen that is fluidly coupled with the one or more cooling channels. The shaft may include at least one power rod that is electrically coupled with at least one of the plurality of bipolar electrodes.

In some embodiments, the chambers may include a cooling assembly that is fluidly coupled with the one or more cooling channels. The cooling assembly may include a chiller that cools a fluid to a predefined temperature and one or more valves that control flow rate of the fluid to and from the one or more cooling channels. The multi-zone heating assembly may include at least four heater zones. The puck may define a plurality of edge purge channels. The first plate may define one or more backside gas channels. The chambers may include a heating element that actively heats the shaft. The at least one thermal insulator may include a plurality of inner insulators and a plurality of outer insulators. Each outer insulator may be spaced apart from and surrounds a respective one of the inner insulators. Each outer insulator may include a fluorine resistant material. The chambers may include an edge ring seated atop a peripheral edge of the puck. The puck may define a plurality of edge purge channels. Each of the plurality of edge purge channels may be disposed beneath the edge ring. The edge ring may direct a purge gas from the plurality of edge purge channels to an edge region of the substrate support surface.

Some embodiments of the present technology may encompass low temperature electrostatic chuck assemblies. The assemblies may include a puck. The puck may include a first plate including an electrically insulating material. The first plate may define a substrate support surface. The puck may include a multi-zone heating assembly that is thermally coupled with the first plate. The puck may include a plurality of bipolar electrodes embedded within the electrically insulating material. The puck may include a second plate that defines one or more cooling channels for a heat exchange fluid. The assemblies may include at least one thermal insulator disposed beneath the second plate. The assemblies may include a facility plate disposed beneath the at least one thermal insulator. The assemblies may include a base plate disposed beneath the facility plate. The assemblies may include a shaft. The shaft may include at least one heater rod that is coupled with the multi-zone heating assembly. The shaft may include at least one cooling fluid lumen that is fluidly coupled with the one or more cooling channels. The shaft may include at least one power rod that is electrically coupled with at least one of the plurality of bipolar electrodes.

In some embodiments, the assemblies may include a third plate disposed against a lower surface of the second plate. The lower surface of the second plate may define one or more grooves that form the one or more cooling channels when the third plate is positioned against the lower surface of the second plate. The first plate may define one or more backside gas channels. The puck may define a plurality of edge purge channels. Each of the plurality of edge purge channels may include a radial portion that extends through the base plate and a vertical portion that extends through at least a portion of the puck. The assemblies may include a heating element that actively heats the shaft. The assemblies may include an adapter plate that couples the pedestal base with the shaft. The first plate may have smaller diameter than other plates such that purge channels extend outward of substrate support surface. The multi-zone heating assembly may be printed on a surface of the first plate.

Some embodiments of the present technology may encompass etching chambers. The chambers may include a chamber body. The chambers may include a showerhead positioned atop the chamber body. The chambers may include a faceplate positioned above the showerhead. A plasma region may be defined between the showerhead and the faceplate. The chambers may include an electrostatic chuck assembly disposed within an interior of the chamber body. The electrostatic chuck assembly may include a puck. The puck may include a first plate including an electrically insulating material. The first plate may define a substrate support surface. The puck may include a multi-zone heating assembly that is thermally coupled with the first plate. The puck may include a plurality of bipolar electrodes embedded within the electrically insulating material. The puck may include a second plate that defines one or more cooling channels for a heat exchange fluid. The assembly may include at least one thermal insulator disposed beneath the second plate. The assembly may include a facility plate disposed beneath the at least one thermal insulator. The assembly may include a base plate disposed beneath the facility plate. The assembly may include a shaft. The shaft may include at least one heater rod that is coupled with the multi-zone heating assembly. The shaft may include at least one cooling fluid lumen that is fluidly coupled with the one or more cooling channels. The shaft may include at least one power rod that is electrically coupled with at least one of the plurality of bipolar electrodes.

Such technology may provide numerous benefits over conventional systems and techniques. For example, embodiments of the present technology may utilize electrostatic chuck designs that are suitable for use in low temperature etch operations, such as processing for etching materials such as silicon germanium. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2A shows a schematic cross-sectional view of an exemplary processing chamber according to some embodiments of the present technology.

FIG. 2B shows a detailed view of a portion of the processing chamber illustrated in FIG. 2A according to some embodiments of the present technology.

FIG. 3A shows a schematic cross-sectional view of an exemplary chuck assembly according to some embodiments of the present technology.

FIG. 3B shows a partial schematic cross-sectional view of the chuck assembly of FIG. 3A.

FIG. 3C shows an exploded view of the chuck assembly of FIG. 3A.

FIG. 3D shows a partially exploded view of the chuck assembly of FIG. 3A.

FIG. 3E illustrates a schematic top view of a base plate of the chuck assembly of FIG. 3A.

FIG. 3F illustrates a schematic top view of an adapter plate of the chuck assembly of FIG. 3A.

FIG. 4 shows a schematic cross-sectional view of an exemplary chuck assembly according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Due to the properties of certain materials (such as, but not limited to, silicon germanium), various etching processing may need to be performed at low temperatures, such as at temperatures of between about −30° C. to 20° C. Conventionally, such processes utilize vacuum chucks to hold a substrate on a substrate support during such etching operations. However, the use of a vacuum chuck may concentrate chucking forces in certain areas (e.g., at the vacuum ports), which may increase the stress applied to the substrate and any film deposited thereon. Additionally, conventional chucks used in etching operations have simple heater systems, which may result in temperature non-uniformity issues, especially radially.

The present technology overcomes these challenges by providing electrostatic chuck assemblies that are designed for use in low temperature operations, including etching operations. The use of an electrostatic chuck may help provide more uniform chucking force across a surface area of the substrate, while also being usable in vacuum chamber environments. Additionally, embodiments may include multi-zone heating assemblies that may enable the temperature of the chuck assembly (and subsequently the substrate) to be tuned, which may further improve the temperature and/or etch rate uniformity of the substrate. Embodiments may include backside gas flow and/or edge purge gas, which may help improve temperature uniformity and prevent etchants from reaching a backside and/or bevel of the substrate.

Although the remaining disclosure will routinely identify specific etching processes utilizing the disclosed technology, it will be readily understood that the systems and methods are equally applicable to other deposition, etching, and cleaning chambers, as well as processes as may occur in the described chambers. Accordingly, the technology should not be considered to be so limited as for use with these specific deposition processes or chambers alone. The disclosure will discuss one possible system and chamber that may include electrostatic chuck assemblies according to embodiments of the present technology before additional variations and adjustments to this system according to embodiments of the present technology are described.

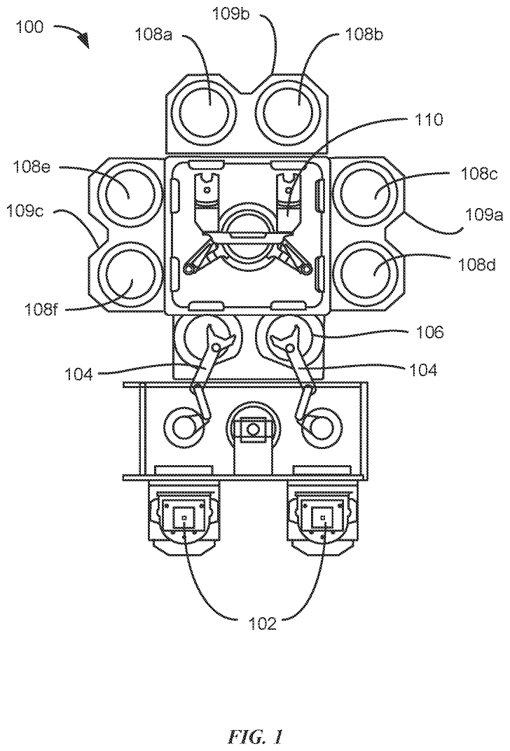

FIG. 1 shows a top plan view of one embodiment of a processing system 100 of deposition, etching, baking, and curing chambers according to embodiments. In the figure, a pair of front opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in chamber(s) separated from the fabrication system shown in different embodiments. It will be appreciated that additional configurations of deposition, etching, annealing, and curing chambers for dielectric films are contemplated by system 100.

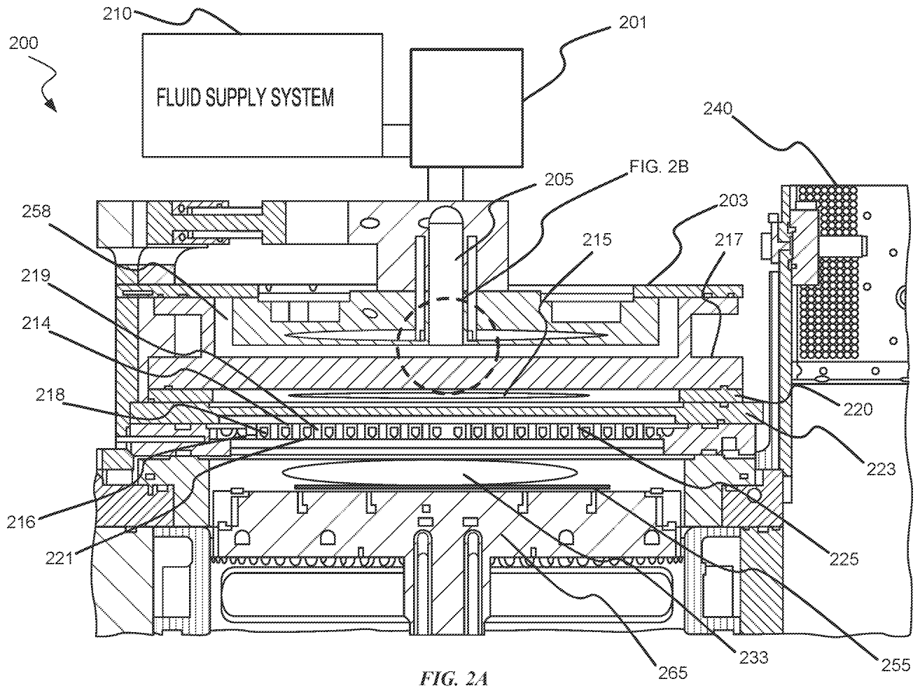

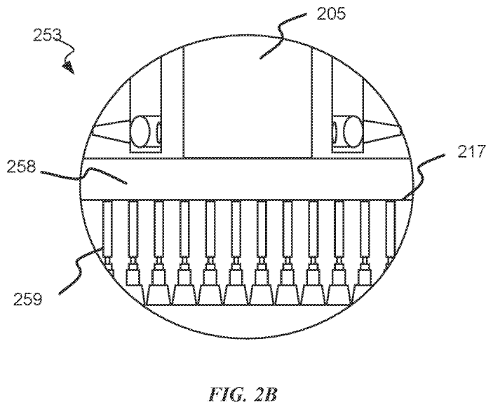

FIG. 2A shows a cross-sectional view of an exemplary process chamber system 200 with partitioned plasma generation regions within the processing chamber. During film etching, e.g., titanium nitride, tantalum nitride, tungsten, silicon, polysilicon, silicon oxide, silicon nitride, silicon oxynitride, silicon oxycarbide, etc., a process gas may be flowed into the first plasma region 215 through a gas inlet assembly 205. A remote plasma system (RPS) 201 may optionally be included in the system, and may process a first gas which then travels through gas inlet assembly 205. The inlet assembly 205 may include two or more distinct gas supply channels where the second channel (not shown) may bypass the RPS 201, if included.

A cooling plate 203, faceplate 217, ion suppressor 223, showerhead 225, and a substrate support 265, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may include aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., SiNx:SiOx etch ratios, Si:SiOx etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if an exposed region of material is oxide, this material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

The gas distribution assemblies such as showerhead 225 for use in the processing chamber section 200 may be referred to as dual channel showerheads (DCSH). The dual channel showerhead may provide for etching processes that allow for separation of etchants outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the gas distribution assembly 225.

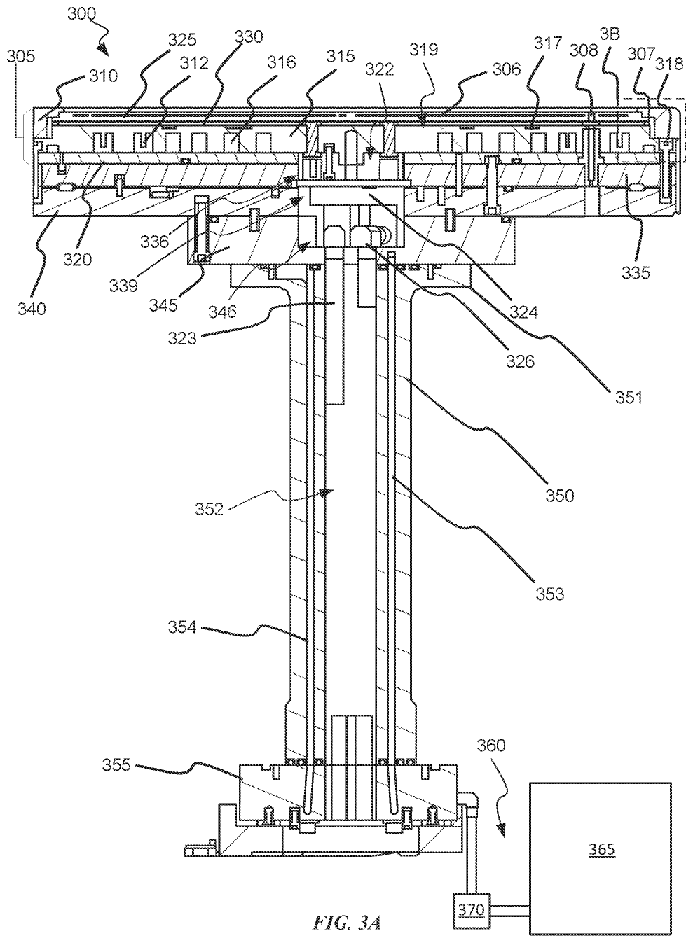

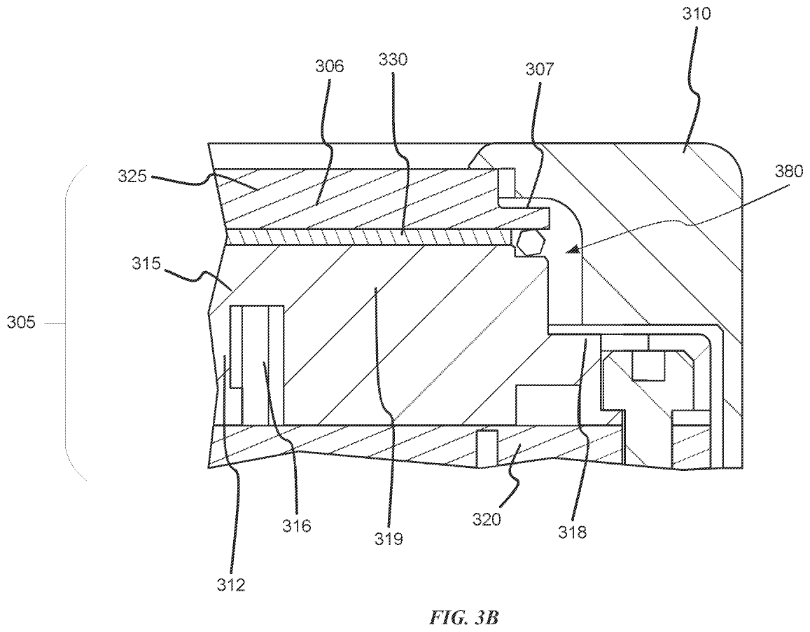

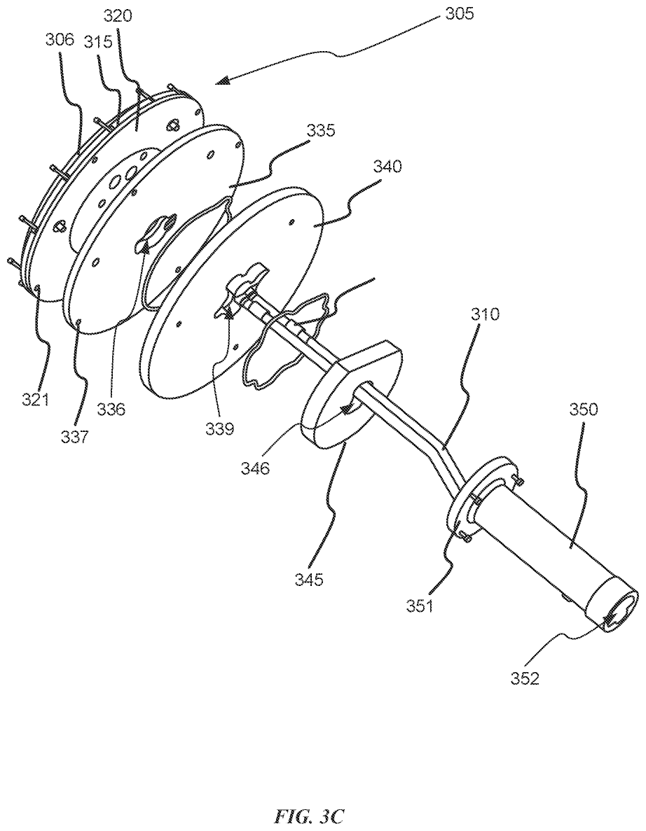

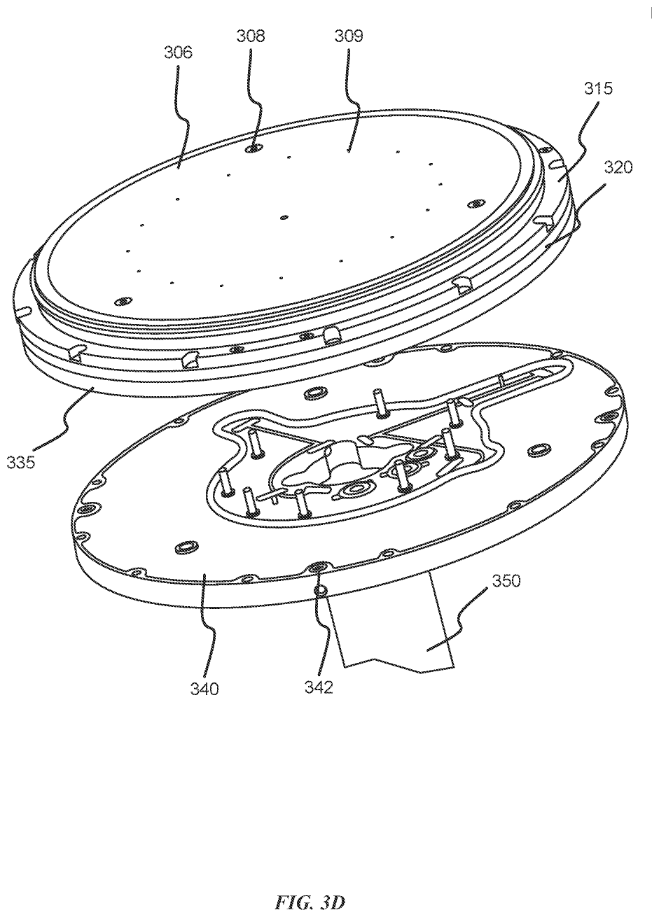

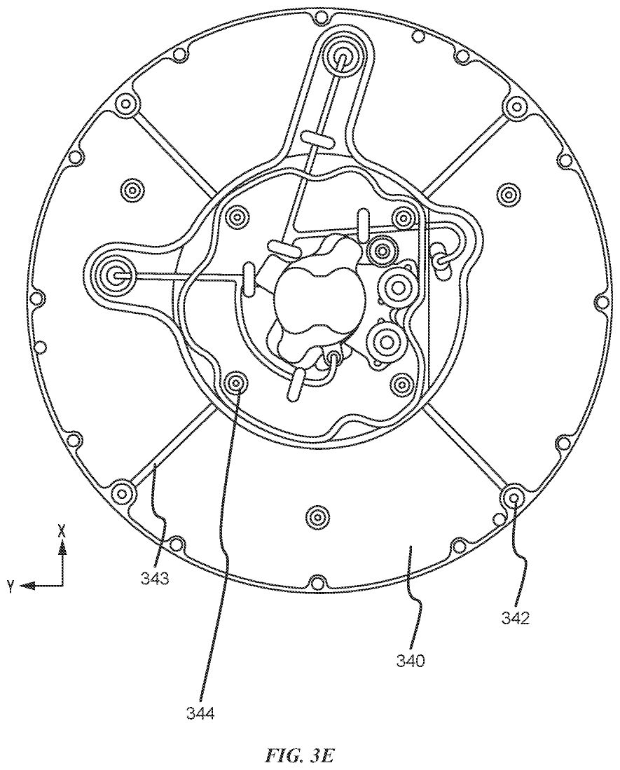

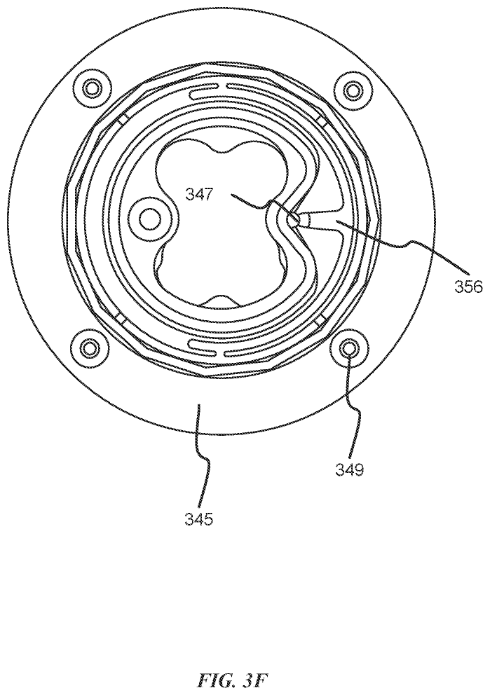

FIGS. 3A-3C show an exemplary electrostatic chuck assembly 300 according to some embodiments of the present technology. The electrostatic chuck assembly 300 may be used as a substrate support, and may be used in any chamber or system previously described, as well as any other chamber or system that may benefit from the electrostatic chuck assembly 300. For example, the electrostatic chuck assembly 300 may be used as pedestal 265 and may be positioned within an interior of a chamber body of an etching chamber and below a showerhead and/or other gas delivery system. The electrostatic chuck assembly 300 may be similar to the pedestal 265 and may include any of the features described in relation to pedestal 265. Electrostatic chuck assembly 300 may include a puck 305, which may be formed from one or more plates. For example, puck 305 may include a first plate 306 that defines a substrate support surface. The substrate support surface may be sized and shaped to substantially match that of a substrate that is supported atop the substrate support surface. In some embodiments, an outer edge 307 of first plate 306 may be recessed relative to a medial portion (e.g., the substrate support surface) of first plate 306. This may enable an edge ring 310 to be seated atop a peripheral edge of puck 305, including being atop outer edge 307, with a top surface of edge ring 310 being spaced above the outer edge 307 to form a purge plenum 380 that may direct a purge gas toward a bevel of a substrate positioned atop the substrate support surface. First plate 306 may define a plurality of apertures therethrough. For example, first plate 306 may define a plurality of lift pin apertures 308 that may receive lift pins used to effectuate transfer of substrates to and from chuck assembly 300. First plate 306 may define a number of backside gas channels 309. Backside gas channels 309 may be provided in any arrangement, such as in one or more annular rings. Backside gas channels 309 may be fluidly coupled to one or more gas sources that may provide a purge gas and/or a thermal gas (such as a heating and/or cooling gas) that may be delivered to the backside of a substrate to assist in maintaining the substrate at a desired temperature for a given processing operation. In some embodiments, the substrate support surface may define one or more grooves that may help circulate the backside gas from backside gas channels 309 to other regions of the substate support surface. For example, a recursive groove may be formed from a number of annular segments at different radial distances from a center of the substrate support surface and a number of radial segments that connect the various annular segments. In some embodiments, first plate 306 may be formed from a dielectric material, such as a ceramic. In other embodiments, first plate 306 may be formed from a processing chamber-compatible material such as, but not limited to, an electrical conductor such as aluminum. In some embodiments, the conductive material may be coated with a dielectric material.

Puck 305 may include a second plate 315 or cooling plate that is coupled with a bottom surface of the first plate 306. Second plate 315 may be formed from a thermally conductive material (such as, but not limited to, aluminum), which may facilitate efficient heat transfer between first plate 306 and second plate 315. Second plate 315 may define one or more cooling channels 316 that may be used circulate a cooling fluid to help cool puck 305. Cooling channels 316 may be formed within one of the surfaces of second plate 315. For example, as illustrated, cooling channels 316 are formed in a bottom surface of second plate 315. In some embodiments, second plate 315 may include a single recursive cooling channel 316 that distributes the cooling fluid across a substantial portion of second plate 315. Some or all of cooling channels 316 may include fins 312, which may increase the surface area of cooling channels 316 to enhance the thermal transfer between second plate 315 and the cooling fluid. A top surface of second plate 315 may define one or more backside gas grooves 317. Backside gas grooves 317 may extend about the top surface of second plate 315 and may fluidly couple backside gas channels 309 with a backside gas port that extends through a portion of puck 305.

A top surface of second plate 315 may include a recessed edge region 318 and a medial region 319 atop which first plate 306 may be mounted. Recessed edge region 318 may extend radially beyond a peripheral edge of first plate 306. A portion of edge ring 310 may be positioned atop recessed edge region 318, with a top surface of edge ring 310 being spaced above the recessed edge region 318 to form a portion of the purge plenum 380 that may direct a purge gas toward a bevel of a substrate positioned atop the substrate support surface. Recessed edge region 318 may define a plurality of edge purge channels that are disposed beneath edge ring 310 and that deliver purge gas to the purge plenum 380.

In some embodiments, puck 305 may include a third plate 320 disposed against a lower surface of second plate 315. Third plate 320 may cover open ends of cooling channels 316 formed in the lower surface of second plate 315, which may take the form of grooves. Third plate 320 may be annular in shape and may define a central aperture 322 in some embodiments. For example, heater power supply lines may be disposed within a bracket 324 that may be received within central aperture 322. An edge region of third plate 320 may define a number of edge purge channels 321 that extend through a thickness of third plate 320 and that may be aligned with the edge purge channels of second plate 315 to form a continuous purge flow path that is fluidly coupled with the purge plenum 380.

Puck 305 may include one or more chucking electrodes 325 embedded within the electrically insulating material of first plate 306. For example, chucking electrodes 325 may include a mesh or grid that is embedded in the ceramic of first plate 306 and may be coupled to a DC supply (or other power supply) and induce an electrostatic potential between a surface of the ceramic and a workpiece disposed on the surface of the ceramic when the electrode 325 is electrified. In some embodiments, chucking electrodes 325 may be monopolar electrodes, while in other embodiments the chucking electrodes 325 may include bipolar electrodes. Puck 305 may include a heating assembly 330 that may be thermally coupled with first plate 306. Heating assembly 330 may include one or more heating coils, lines, or plates that are embedded within, printed upon, and/or coupled against first plate 306. Heating assembly 330 may be positioned between chucking electrodes 325 and second plate 315 in some embodiments. In some embodiments, heating assembly 330 may include a multi-zone heating assembly, which may include two or more independently controllable zones. The use of a multi-zone heating assembly may enable various non-uniformity issues, such as radial non-uniformity issues, to be corrected. Multi-zone heating assemblies may include at least two zones, at least three zones, at least four zones, at least five zones, at least six zones, or more. Each zone may be a same or different shape and/or size. For example, each zone may be circular, wedge shaped, arcuate, radial, annular, and/or another shape.

Chuck assembly 300 may include a thermal insulator, which may be in the form of a ceramic insulator 335 that is disposed beneath puck 305 in some embodiments. For example, ceramic insulator 335 may be coupled with a bottom surface of second plate 315 or third plate 320. Ceramic insulator 335 may be formed from a ceramic material, such as, but not limited to, aluminum oxide or aluminum nitride. Ceramic insulator 335 may help prevent or limit thermal transfer between puck 305 and components of chuck assembly 300 that are disposed beneath the ceramic insulator 335. Ceramic insulator 335 may define a central aperture 336 that may provide access for a number of heater power lines, which may be coupled with bracket 324. In some embodiments, a peripheral edge region of ceramic insulator 335 may define a plurality of edge purge channels 337 that extend through a thickness of ceramic insulator 335 and that may be aligned with the edge purge channels 321 of third plate 320 and the edge purge channels of second plate 315 to form a continuous purge flow path that is fluidly coupled with the purge plenum 380.

Chuck assembly 300 may include a base plate 340 that is disposed beneath ceramic insulator 335. For example, a top surface of base plate 340 may be coupled against a bottom surface of ceramic insulator 335. Base plate 340 may define a central aperture 339 that may provide access for a number of heater power lines, which may be coupled with bracket 324. In some embodiments, a peripheral edge region of base plate 340 may define a plurality of edge purge channels 342 that extend partially through a thickness of base plate 340 and that may be aligned with the edge purge channels 337 of ceramic insulator 335, edge purge channels 321 of third plate 320, and the edge purge channels of second plate 315 to form a continuous purge flow path that is fluidly coupled with the purge plenum 380. Each edge purge channel 342 may include a radial portion 343 that extends laterally through base plate 340. Each radial portion 343 may be coupled with a purge port 344 that extends through a bottom surface of base plate 340. As illustrated, there are four purge ports 344 that are each coupled with a single purge channel 342, however other numbers of purge ports 344 and/or purge channels 342 may be utilized in various embodiments. Continuous purge channels may be formed from purge ports 344 to the outlet ends of the edge purge channels formed in second plate 315. Each purge channel may include a radial portion (e.g., radial portion 343) and a vertical portion (e.g., edge purge channels 342, 337, 321, and edge purge channels of second plate 315.

Chuck assembly 300 may include an adapter plate 345 that couples base plate 345 with a shaft 350. Adapter plate 345 may be coupled with a bottom surface of base plate 345 and may extend about and/or cover one or more components, such as cooling fluid lumens 323, fluid weldments 326 that may circulate cooling fluid through cooling channels 316, heater power lines, and/or other components. Adapter plate 345 may define a central aperture 346 through a thickness of adapter plate 345, which may enable components such as cooling fluid lumens 323 and heater power lines to extend through adapter plate 345 and into base plate 340, ceramic insulator 335, and puck 305. A bottom surface of adapter plate 345 may define a purge port 347 that is fluidly coupled with one or more channels 356 that may distribute a purge gas to a number of purge ports 349 that extend from the upper surface of adapter plate 345. As illustrated, a single recursive channel 356 includes a first radial portion that extends outward from purge port 347 and couples with an arcuate portion. The arcuate portion include a number of radial segments that extend outward and couple with an annular portion. The annular portion is coupled with a number of additional radial portions that extend outward to purge ports 349. It will be appreciated that the design of recursive channel 356 is provided as a single example and that other channel designs are possible in various embodiments.

Shaft 350 may be coupled with a bottom surface of adapter plate 345. For example, a top end of shaft 350 may include a flange 351 that may be positioned against and fastened to adapter plate 345. Shaft 350 may define an open interior 352 that may receive various components of chuck assembly 300, such as (but not limited to) cooling fluid lumens 323, heater power rods or lines 353 (which may be coupled with heater assembly 330), DC or other power rods 354 for providing power to chucking electrodes 325, and/or other components. In some embodiments, shaft 350 may be coupled with a shaft hub 355, which may include a heating element (such as a resistive heating element) that actively heats shaft 350. Shaft 350 may be heated to help prevent byproduct deposits and condensation/moisture buildup on shaft 350 during processing operations. Adapter plate 345 and/or base plate 340 may be formed from thermally conductive materials (such as aluminum) such that heat from shaft 350 may also heat adapter plate 345 and base plate 340 to help prevent condensation/moisture buildup and deposition of byproducts on adapter plate 345 and base plate 340 during processing operations. Ceramic insulator 335 may thermally isolate puck 305 from the heated lower components, enabling puck 305 to remain chilled to maintain a substrate at a sufficiently cold temperature to facilitate etching of materials such as SiGe.

Cooling channels 316 and cooling fluid lumens 323 may be fluidly coupled with a cooling assembly 360 that supplies a cooling fluid to chuck assembly 300. Cooling assembly 360 may include a chiller 365 that cools the fluid to a predefined temperature (such as between −40° C. and 50° C.) and one or more valves 370 and/or flow controllers that control a flow rate of the fluid to and from the cooling channels 316 and cooling fluid lumens 323.

Chuck assembly 300 may include a number of O-rings, gaskets, and/or other sealing elements that help seal the various interfaces between plates of chuck assembly 300. In some embodiments, each interface between plates of chuck assembly 300 may include at least one sealing element. For example, at least one sealing element may be disposed about at least some features of each plate to isolate components that may be exposed to the vacuum environment within the processing chamber from components that are disposed at atmospheric pressure. Each O-ring may be disposed as radially inward as possible while still extending outward of the components being isolated from a given pressure environment. Such positioning may help isolate the O-rings from the cold processing temperatures, which may make the O-rings brittle. To accommodate such positioning, some or all of the O-rings may be irregularly shaped such that on portions of a given interface that include no components to be isolated the O-rings may be drawn as radially inward as possible.

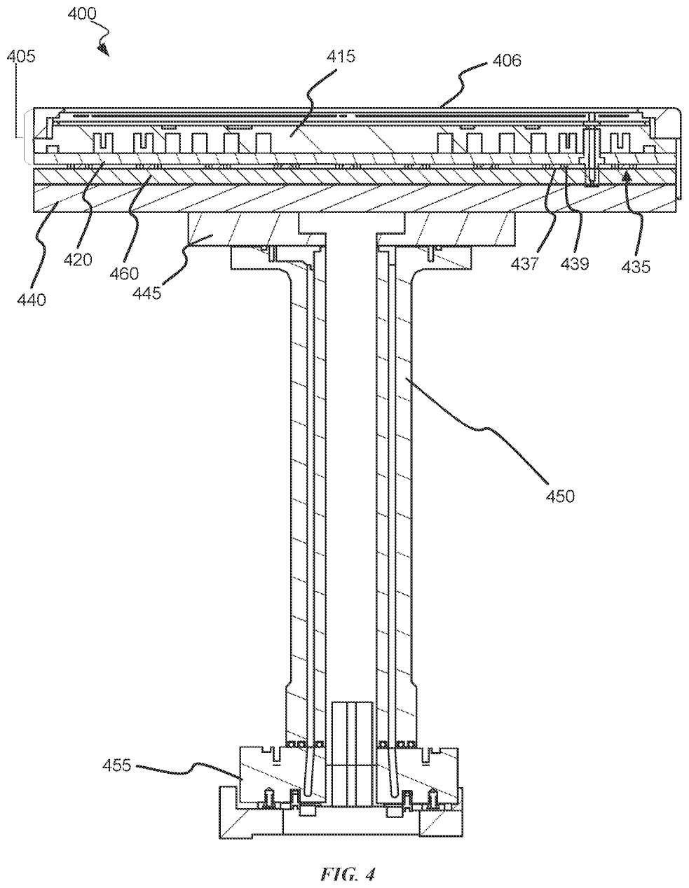

FIG. 4 shows an exemplary electrostatic chuck assembly 400 according to some embodiments of the present technology. The electrostatic chuck assembly 400 may be used as a substrate support and may be used in any chamber or system previously described, as well as any other chamber or system that may benefit from the electrostatic chuck assembly 400. For example, the electrostatic chuck assembly 300 may be used as pedestal 265 and may be positioned within an interior of a chamber body of an etching chamber and below a showerhead and/or other gas delivery system. The electrostatic chuck assembly 300 may be similar to the pedestal 265 and electrostatic chuck assembly 300 and may include any of the features described in relation to pedestal 265 and/or electrostatic chuck assembly 300. Electrostatic chuck assembly 400 may include a puck 405, which may be formed from one or more plates. For example, puck 405 may include a first plate 406 that defines a substrate support surface. Puck 405 may include a second plate 415 or cooling plate that is coupled with a bottom surface of the first plate 406. Second plate 415 may be formed from a thermally conductive material (such as, but not limited to, aluminum), which may facilitate efficient heat transfer between first plate 406 and second plate 415. Second plate 415 may define one or more cooling channels that may be used circulate a cooling fluid to help cool puck 405. In some embodiments, puck 405 may include a third plate 420 disposed against a lower surface of second plate 415. Third plate 420 may cover open ends of the cooling channels formed in the lower surface of second plate 415, which may take the form of grooves.

Chuck assembly 400 may include one or more thermal insulators 435 that are disposed beneath puck 405 in some embodiments. For example, each thermal insulator 435 may be coupled with a bottom surface of second plate 415 or third plate 420 and/or otherwise disposed between puck 405 and a base plate 440. In some embodiments, thermal insulator 435 may take the form of a plate, such as ceramic plate 335. In other embodiments, thermal insulator 435 may take other forms. For example, the thermal insulators 435 may include washers, plates, tablets, gaskets, and/or other structure that may thermally decouple puck 405 from lower components of chuck assembly 400, such as base plate 440, an adapter plate 445, a stem 450, and/or a cooling hub 455. Such thermal decoupling may enable puck 405 to be effectively chilled for low temperature processing operations while the lower components of chuck assembly 400 may be heated to higher temperatures to prevent deposition on such components. Thermal insulators 435 may be formed from and/or otherwise include polymeric materials, ceramic materials, inorganic materials, organic materials (e.g., polyamides, PTFE, etc.), and/or other materials that may effectively thermally decouple puck 405 from the lower components of chuck assembly 400. In some embodiments, thermal insulators 435 may include materials and structures that may provide a thermal conductance of no greater than 20 W/mK, no greater than 15 W/mK, no greater than 10 W/mK, no greater than 5 W/mK, no greater than 1 W/mK, no greater than 0.75 W/mK, no greater than 0.5 W/mK, no greater than 0.25 W/mK, no greater than 0.2 W/mK, or less.

In the illustrated embodiment, each thermal insulator 435 includes an inner insulator 437 and an outer insulator 439. Each outer insulator 439 may be spaced apart from and surround the inner insulator 437. For example, each outer insulator 439 may be an annular member, such as a washer or O-ring. Each inner insulator 437 may be a tablet or other structure that may help space apart and thermally isolate puck 405 from other components of chuck assembly 400. In some embodiments, the inner insulators 437 and outer insulators 439 may be formed from a same material, while in other embodiments different materials may be used for inner insulators 437 and outer insulators 439. At least the outer insulators 439 may be formed from a fluorine resistant material, which may enable outer insulators 439 to be exposed to the chamber environment and process gases. For example, an area outside of outer insulators 439 may be open and exposed to the processing environment. This exposure may enable a space between puck 405 and base plate 440 to be maintained at vacuum or other low pressure, which may better thermally decouple the components. Thermal insulators 435 (including inner insulators 437 and/or outer insulators 439) may have various thicknesses. For example, thicker thermal insulators 435 (e.g., plates) may have thicknesses of between 5 mm and 20 mm or more, while thinner thermal insulators 435 (e.g., tablets, washers, O-rings, gaskets, etc.) may have thicknesses of between about 0.25 mm and 5 mm, between or about 0.5 mm and 2.5 mm, or between or about 1 mm and 2 mm. Any number of thermal insulators 435 may be used in various embodiments. For example, chuck assembly 400 may include one or more thermal insulators, two or more thermal insulators, three or more thermal insulators, four or more thermal insulators, five or more thermal insulators, ten or more thermal insulators, fifteen or more thermal insulators, twenty or more thermal insulators, or more.

Chuck assembly 400 may include a facility plate 460 that may be disposed beneath thermal insulators 435 in some embodiments. For example, facility plate 460 may be disposed between thermal insulators 435 and base plate 440. Facility plate 460 may be formed from a thermally conductive material, such as (but not limited to) aluminum. In some embodiments, facility plate 460 may accommodate driving mechanisms that raise and lower lift pins. Facility plate 460 may accommodate fluid connections that circulate cooling fluid between the cooling channels of second plate 415 and a cooling source (such as via stem 450). Facility plate 460 may accommodate electrical connections, such as power rods for chucking electrodes and/or a heating assembly of chuck assembly 400. For example, facility plate 460 may provide an interface for the connections to a respective terminus.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an aperture” includes a plurality of such apertures, and reference to “the plate” includes reference to one or more plates and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing chamber, comprising:
a chamber body;
a showerhead positioned atop the chamber body; and
an electrostatic chuck assembly disposed within an interior of the chamber body, the electrostatic chuck assembly comprising:
a puck comprising:
a first plate comprising an electrically insulating material, the first plate defining a substrate support surface;
a multi-zone heating assembly that is thermally coupled with the first plate;
a plurality of bipolar electrodes embedded within the electrically insulating material; and
a second plate that defines one or more cooling channels for a heat exchange fluid;
at least one thermal insulator disposed beneath the second plate;
a facility plate disposed beneath the at least one thermal insulator;
a base plate disposed beneath the facility plate; and
a shaft comprising:
at least one heater rod that is coupled with the multi-zone heating assembly;
at least one cooling fluid lumen that is fluidly coupled with the one or more cooling channels; and
at least one power rod that is electrically coupled with at least one of the plurality of bipolar electrodes.

2. The semiconductor processing chamber of claim 1, further comprising:
a cooling assembly that is fluidly coupled with the one or more cooling channels.

3. The semiconductor processing chamber of claim 2, wherein:
the cooling assembly comprises a chiller that cools a fluid to a predefined temperature and one or more valves that control flow rate of the fluid to and from the one or more cooling channels.

4. The semiconductor processing chamber of claim 1, wherein:
the multi-zone heating assembly comprises at least four heater zones.

5. The semiconductor processing chamber of claim 1, wherein:
the puck defines a plurality of edge purge channels.

6. The semiconductor processing chamber of claim 1, wherein:
the first plate defines one or more backside gas channels.

7. The semiconductor processing chamber of claim 1, further comprising:
a heating element that actively heats the shaft.

8. The semiconductor processing chamber of claim 1, wherein:
the at least one thermal insulator comprises a plurality of inner insulators and a plurality of outer insulators;
each outer insulator is spaced apart from and surrounds a respective one of the inner insulators; and
each outer insulator comprises a fluorine resistant material.

9. The semiconductor processing chamber of claim 1, further comprising:
an edge ring seated atop a peripheral edge of the puck. 2

10. The semiconductor processing chamber of claim 9, wherein:
the puck defines a plurality of edge purge channels;
each of the plurality of edge purge channels is disposed beneath the edge ring; and
the edge ring directs a purge gas from the plurality of edge purge channels to an edge region of the substrate support surface.

11. A low temperature electrostatic chuck assembly, comprising:
a puck comprising:
a first plate comprising an electrically insulating material, the first plate defining a substrate support surface;
a multi-zone heating assembly that is thermally coupled with the first plate;
a plurality of bipolar electrodes embedded within the electrically insulating material; and
a second plate that defines one or more cooling channels for a heat exchange fluid;
at least one thermal insulator disposed beneath the second plate;
a facility plate disposed beneath the at least one thermal insulator;
a base plate disposed beneath the facility plate; and
a shaft comprising:
at least one heater rod that is coupled with the multi-zone heating assembly;
at least one cooling fluid lumen that is fluidly coupled with the one or 17 more cooling channels; and
at least one power rod that is electrically coupled with at least one of the plurality of bipolar electrodes.

12. The low temperature electrostatic chuck assembly of claim 11, further comprising:
a third plate disposed against a lower surface of the second plate, wherein the lower surface of the second plate defines one or more grooves that form the one or more cooling channels when the third plate is positioned against the lower surface of the second plate.

13. The low temperature electrostatic chuck assembly of claim 11, wherein:
the first plate defines one or more backside gas channels.

14. The low temperature electrostatic chuck assembly of claim 11, wherein:
the puck defines a plurality of edge purge channels.

15. The low temperature electrostatic chuck assembly of claim 14, wherein:
each of the plurality of edge purge channels comprises a radial portion that extends through the pedestal base and a vertical portion that extends through at least a portion of the puck.

16. The low temperature electrostatic chuck assembly of claim 11, further comprising:
a heating element that actively heats the shaft.

17. The low temperature electrostatic chuck assembly of claim 11, further comprising:
an adapter plate that couples the base plate with the shaft.

18. The low temperature electrostatic chuck assembly of claim 11, wherein:
the first plate has smaller diameter than other plates such that purge channels extend outward of substrate support surface.

19. The low temperature electrostatic chuck assembly of claim 11, wherein:
the multi-zone heating assembly is printed on a surface of the first plate.

20. An etching chamber, comprising:
a chamber body;
a showerhead positioned atop the chamber body;
a faceplate positioned above the showerhead, wherein a plasma region is defined between the showerhead and the faceplate; and
an electrostatic chuck assembly disposed within an interior of the chamber body, the electrostatic chuck assembly comprising:
a puck comprising:
a first plate comprising an electrically insulating material, the first plate defining a substrate support surface;
a multi-zone heating assembly that is thermally coupled with the first plate;
a plurality of bipolar electrodes embedded within the electrically insulating material; and
a second plate that defines one or more cooling channels for a heat exchange fluid;
at least one thermal insulator disposed beneath the second plate;
a facility plate disposed beneath the at least one thermal insulator;
a base plate disposed beneath the facility plate; and
a shaft comprising:
at least one heater rod that is coupled with the multi-zone heating assembly;
at least one cooling fluid lumen that is fluidly coupled with the one or more cooling channels; and
at least one power rod that is electrically coupled with at least one of the plurality of bipolar electrodes.
